(19) United States
(12) Patent Application Publication
(10) Pub. No.: US 2025/0318342 A1
(43) Pub. Date: Oct. 9, 2025

(54) A LIGHTING DEVICE

(71) Applicant: SIGNIFY HOLDING B.V., EINDHOVEN (NL)

(72) Inventors: KEVIN THOMAS WORM, EINDHOVEN (NL); BART BONGERS, EINDHOVEN (NL); MARTINA KRULIS, EINDHOVEN (NL); MARTINUS HERMANUS WILHELMUS MARIA VAN DELDEN, VENLO (NL)

(21) Appl. No.: 18/864,990

(22) PCT Filed: May 2, 2023
(86) PCT No.: PCT/EP2023/061514

§ 371 Date: Nov. 12, 2024

(30) Foreign Application Priority Data
May 12, 2022 (EP) 22172934.6

(51) Int. Cl. H10H 29/14; H05B 47/155; H05B 47/17; H10H 29/80

(52) U.S. Cl. CPC H10H 29/142; H05B 47/155; H05B 47/17; H10H 29/882

(57) ABSTRACT

A lighting device (1) configured for providing a viewer with immersive light experiences and comprising an optical light mixing unit (2) comprising a diffuse light exit window (3), a first plurality of LED light sources (4) adapted for, in operation, emitting first LED light source light (17), the first plurality of LED light sources being non-imaging LED light sources, and being arranged such as to, in operation, homogeneously illuminate the light exit window, and at least one second plurality of LED light sources (5) adapted for, in operation, emitting second LED light source light (18), the second plurality of LED light sources being imaging LED light sources, and comprising one or more image forming elements (6), and the second plurality of LED light sources (5) being arranged between the first plurality of LED light sources (4) such as to, in operation, non-homogeneously illuminate the light exit window (3).

### FIELD OF THE INVENTION

The invention relates to a lighting device configured for providing a viewer with immersive light experiences.

As used herein, the term “immersive light experiences” is intended to refer to light experiences generating a three-dimensional image which appears to surround the user at least partially. Such immersive light experiences may for instance be environmental light experiences simulating nature or naturally occurring phenomena, such as daylight, clouds, plants, trees and water.

As used herein, the term “imaging LED light source” is intended to refer to a LED light source configured to form, when in operation, an image or a part of an image forming part of an immersive light experience.

As used herein, the term “non-imaging LED light source” is intended to refer to a LED light source which, when in operation, does not form an image or a part of an image, but still provides light forming part of an immersive light experience.

### BACKGROUND OF THE INVENTION

In the known art, immersive light scene experiences is the result of different modulation layers working together, as one system. At the highest level, the light scene experience can be divided into four sub layers. The first layer is a circadian layer configured to simulate brightness, direction and time of day useful for reproducing for instance time and location. The second layer is an atmospheric layer configured to simulate sunniness, spatial variations and random dynamics useful for reproducing for instance cloud formations. The third layer is an environmental layer configured to simulate textures, pixilation and stochastic motion useful for reproducing for instance trees plants and water. Finally, the fourth layer is an architectural layer, for instance in the form of a canvas, forming layout and spatial mapping of the device. The fourth layer may also comprise various instruments. Space wide light scene experiences are predominantly built by the circadian and atmospheric layers, as experienced from the different elements of the architectural layer, whereas the local dynamic experiences are substantially provided by the environmental layer.

Examples of environmental light scene experiences are sparkle, dapple and shadows, comprising elements such as open and closed, texture, pixelation and stochastic motion. Thereby nature or naturally occurring phenomena, such as daylight, clouds, plants, trees and water, may be simulated.

US 2018/0153019 A1 discloses a lighting system configured for daylight emulation. The system includes a plurality of light sources for generating a daylight-emulating output light spectrum. The system also includes a controller for dynamically controlling at least one of the intensity, directionality and color temperature to emulate sun position for at least one of a geography and time of day. The system further includes a networking facility that facilitates data communication with at least one external resource.

U.S. Pat. No. 9,731,840B2 discloses an aircraft interior light unit having a light output over an extended light emission area that includes a flat light distribution body having a front surface, through which the light output is coupled out, and a back surface, wherein at least one of the front surface and the back surface of the flat light distribution body has a plurality of surface irregularities. A plurality of signaling LEDs are being arranged outside of the flat light distribution body and facing towards the back surface of the flat light distribution body.

IT20190018515A discloses a device with a housing, a backlight unit, and a graphical support. The backlight unit has multiple light sources that can be selectively controlled in order to create a graphical representation via the graphical support.

U.S. Pat. No. 9,877,370B discloses a lighting device comprising a first set of light emitting diodes arranged to emit blue light and a second set of light emitting diodes arranged to emit blue light. A first luminescent element is radiationally coupled to the first and second set of light emitting diodes and arranged to convert at least a part of the light. A second luminescent element is radiationally coupled to at least a subset of the second set of light emitting diodes and arranged to convert at least a part of the light. The brightness level of the light emitted by the first set of light emitting diodes and the brightness level of the light emitted by the second set of light emitting diodes is controllable independently.

Known devices, capable of generating environmental light effects, are beamer and projector devices for which “image” forming can be achieved by active or passive modulation of a single high-brightness light source. Active modulation means may comprise matrix display devices, beamers using a combination of laser light sources and a DMD, discrete (mini) LEDs arrays, AMOLEDs, and LCD devices, for example. Passive modulation means may comprise shadow masks, overhead sheets, or physical objects such as plants, placed in the directional shaft of light emerging from the light emitting device. However, several challenges are associated with such devices.

A first challenge is the relatively short lifetime of the high-brightness light sources, especially when compared to discrete LEDs.

A second challenge is that the compact, high brightness, and thus high power, light-source requires cooling, in general achieved by fans, generating audible noise. This noise must be suppressed, especially in office spaces. Cooling devices further also tend to reduce the lifetime of the luminaire, since it is an additional component which can fail.

A third challenge is that the imaging plane of the modulated light source is often located remote or is not available at all, at a wall or floor, for example. Thus, the small and high-brightness light exit window of the light engine may be observable by a system user, at least under given angles of view. For application as office lighting, the devices often exceed acceptable glare, unless arranged in proximity to a projection surface, such as a wall.

A fourth challenge is the static nature of the passive modulation means, such as that of an overhead sheet, for which switching between “images”, for example, requires a change of sheets.

It is therefore desired to propose a new lighting device which overcomes or elevates at least one of the challenges above, whilst ensuring that the “displayed” image can be changed gradually between at least two different optical “image” states, of which one state is a homogenous illuminated state (i.e. there is no image displayed).

### SUMMARY OF THE INVENTION

It is an object of the present invention to overcome the above-described problems, and to provide a new lighting device which overcomes or elevates at least one of the challenges above.

It is a further object of the present invention to provide such a lighting device which also ensures that the “displayed” image can be changed gradually between at least two different optical “image” states, of which one state is a homogenous illuminated state (i.e. there is no image displayed).

According to a first aspect of the invention, these and other objects are achieved by a lighting device configured for providing a viewer with immersive light experiences and comprising an optical light mixing unit comprising a diffuse light exit window, a first plurality of LED light sources adapted for, in operation, emitting first LED light source light, the first plurality of LED light sources being non-imaging LED light sources, and the first plurality of LED light sources being arranged such as to, in operation, homogeneously illuminate the light exit window, and at least one second plurality of LED light sources adapted for, in operation, emitting second LED light source light, the second plurality of LED light sources being imaging LED light sources, where at least one LED light source of the second plurality of LED light sources comprises one or more image forming elements, and where the second plurality of LED light sources is arranged between the first plurality of LED light sources such as to, in operation, non-homogeneously illuminate the light exit window. The side and bottom walls of the optical lighting mixing unit are reflective for the first LED light source light. The LED light sources of the second plurality of LED light sources are arranged to emit light in a direct optical path, i.e. without reflections by one or more of the (side and bottom) walls of the optical light mixing unit, to the light exit window. Providing that the first and second plurality of LED light sources are arranged as described above and such that the lighting device comprises dispersed discrete LEDs, a lighting device which allows for passive cooling is provided for. Thereby, it becomes possible to omit fans and other cooling devices which would otherwise produce unwanted noise. Thus, a lighting device with reduced or no noise, and further with a longer lifetime, is provided for.

LEDs have much larger lifetimes than high-brightness sources. Thus, by providing the first and second plurality of light sources as a first and second plurality of LED light sources, a more robust and durable lighting device with which the service intervals is increased is provided for. As used herein, the term “LED light source” refers to a solid state light source, including superluminescent LEDs and laser diodes, amongst others.

The wording “the second plurality of LED light sources is arranged between the first plurality of LED light sources” refers to an alternating two-dimensional arrangement of one more LEDs of the second plurality of LED light sources and one or more LEDs of the first plurality of LED light sources.

With the above described lighting device, and especially in virtue of at least one LED light source of the second plurality of LED light sources comprising one or more image forming elements, back and side illumination of the one or more image forming elements is obtained. This in turn eliminates the observation of small-sized, high-brightness light exit windows, as associated with for example spot, beamer and projector devices. Thus, with such a lighting device the glare is reduced to an acceptable level. The use of optical lighting mixing unit with reflective walls for the light of the LED light sources from the first plurality of LED light sources, in combination with a diffuse light exit window further reduces glare.

Furthermore, with such a lighting device, no change of sheets is needed for switching between images, for example.

In an embodiment, the one or more image forming elements are one or more of reflective, opaque, translucent and transparent.

In an embodiment, the one or more image forming elements are chosen from the group comprising micro-sheets, foams, fibers, porous 2D-printed or 3D-printed structures, a patterned phosphor provided on the second plurality of LED light sources and a light detouring light guide.

Such types of image forming elements have been shown to be especially suitable for lighting devices having the purpose of providing a viewer with immersive light experiences. Furthermore, such types of image forming elements are simple in structure and cheap to procure and/or produce.

The wording “phosphor” refers to one or more luminescent materials that are configured to convert at least part of the (blue) light of the LED light source into luminescent material light. Especially, the luminescent material light comprises visible light, such as having a color point in the yellow or green. Especially, the luminescent material is configured to convert at least part of the light source light into luminescent material light having an emission band having wavelengths in one or more of (a) the green spectral wavelength range and (b) the yellow spectral wavelength range, wherein the luminescent material comprises a (garnet) luminescent material of the type A3B5O12:Ce, wherein A comprises one or more of Y, La, Gd, Tb and Lu, and wherein B comprises one or more of Al, Ga, In and Sc. Hence, the luminescent material light may e.g. green light or yellow light (or in specific embodiments even orange (dependent upon the composition of the garnet and cerium concentration)). However, other embodiments are also possible, see below. In embodiments, 0.05-10% of the A elements comprise Ce, even more especially 0.05-5%, such as 0.1-5%. Especially, embodiments, 0.1-3% of the A elements comprise Ce, such as up to 2%, like selected from the range of 0.1-1.5%, such as at least above 0.5%.

Hence, in specific embodiments the luminescent material comprises a luminescent material of the type A3B5O12:Ce, wherein A in embodiments comprises one or more of Y, La, Gd, Tb and Lu, especially (at least) one or more of Y, Gd, Tb and Lu, and wherein B in embodiments comprises one or more of Al, Ga, In and Sc. Especially, A may comprise one or more of Y, Gd and Lu, such as especially one or more of Y and Lu. Especially, B may comprise one or more of Al and Ga, more especially at least Al, such as essentially entirely Al. Hence, especially suitable luminescent materials are cerium comprising garnet materials. Embodiments of garnets especially include A3B5O12 garnets, wherein A comprises at least yttrium or lutetium and wherein B comprises at least aluminum. Such garnets may be doped with cerium (Ce), with praseodymium (Pr) or a combination of cerium and praseodymium; especially however with Ce. Especially, B comprises aluminum (Al), however, B may also partly comprise gallium (Ga) and/or scandium (Sc) and/or indium (In), especially up to about 20% of Al, more especially up to about 10% of Al (i.e. the B ions essentially consist of 90 or more mole % of Al and 10 or less mole % of one or more of Ga, Sc and In); B may especially comprise up to about 10% gallium. In another variant, B and O may at least partly be replaced by Si and N. The element A may especially be selected from the group consisting of yttrium (Y), gadolinium (Gd), terbium (Tb) and lutetium (Lu). Further, Gd and/or Tb are especially only present up to an amount of about 20% of A. In a specific embodiment, the garnet luminescent material comprises (Y1-xLux)3B5O12:Ce, wherein x is equal to or larger than 0 and equal to or smaller than 1. The term “:Ce”, indicates that part of the metal ions (i.e. in the garnets: part of the “A” ions) in the luminescent material is replaced by Ce. For instance, in the case of (Y1-xLux)3Al5O12:Ce, part of Y and/or Lu is replaced by Ce. This is known to the person skilled in the art. Ce will replace A in general for not more than 10%; in general, the Ce concentration will be in the range of 0.1 to 4%, especially 0.1 to 2% (relative to A). Assuming 1% Ce and 10% Y, the full correct formula could be (Y0.1Lu0.89Ce0.01)3Al5O12. Ce in garnets is substantially or only in the trivalent state, as is known to the person skilled in the art.

Alternatively or additionally, the luminescent material may e.g. be M2Si5N8:Eu2+ and/or MAlSiN3:Eu2+ and/or Ca2AlSi3O2N5:Eu2+, etc., wherein M comprises one or more of Ba, Sr and Ca, especially in embodiments at least Sr. In specific embodiments, the first luminescent may comprise one or more materials selected from the group consisting of (Ba,Sr,Ca)S:Eu, (Ba,Sr,Ca)AlSiN3:Eu and (Ba,Sr,Ca)2Si5N8:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu2+). For instance, assuming 2% Eu in CaAlSiN3:Eu, the correct formula could be (Ca0.98Eu0.02) AlSiN3. Divalent europium will in general replace divalent cations, such as the above divalent alkaline earth cations, especially Ca, Sr, or Ba. The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Further, the material (Ba,Sr,Ca)2Si5N8:Eu can also be indicated as M2Si5N8:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba1.5Sr0.5Si5N8:Eu (i.e. 75% Ba; 25% Sr). Here, Eu is introduced and replaces at least part of M, i.e. one or more of Ba, Sr, and Ca). Likewise, the material (Ba,Sr,Ca)AlSiN3:Eu can also be indicated as MAlSiN3:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Eu in the above indicated luminescent materials is substantially or only in the divalent state, as is known to the person skilled in the art. Hence, such nitride luminescent materials may also be or comprise converter elements, here especially Eu2+.

The LEDs from the first and/or second plurality of light sources may be selected from one or more of the group of blue, green and red light emitting LEDs.

The terms “visible”, “visible light” or “visible emission” and similar terms refer to light having one or more wavelengths in the range of about 380-780 nm. Herein, UV may especially refer to a wavelength selected from the range of 200-380 nm. The terms “light” and “radiation” are herein interchangeably used, unless clear from the context that the term “light” only refers to visible light. The terms “light” and “radiation” may thus refer to UV radiation, visible light, and IR radiation. In specific embodiments, especially for lighting applications, the terms “light” and “radiation” refer to (at least) visible light. The terms “violet light” or “violet emission” especially relates to light having a wavelength in the range of about 380-440 nm. The terms “blue light” or “blue emission” especially relates to light having a wavelength in the range of about 440-495 nm (including some violet and cyan hues). The terms “green light” or “green emission” especially relate to light having a wavelength in the range of about 495-570 nm. The terms “yellow light” or “yellow emission” especially relate to light having a wavelength in the range of about 570-590 nm. The terms “orange light” or “orange emission” especially relate to light having a wavelength in the range of about 590-620 nm. The terms “red light” or “red emission” especially relate to light having a wavelength in the range of about 620-780 nm. The term “pink light” or “pink emission” refers to light having a blue and a red component. The term “cyan” may refer to one or more wavelengths selected from the range of about 490-520 nm. The term “amber” may refer to one or more wavelengths selected from the range of about 585-605 nm, such as about 590-600 nm.

In an embodiment, the one or more image forming elements are arranged such as to cover the at least one LED light source of the second plurality of LED light sources partially.

Thereby, a lighting device providing a resulting image output with an improved brightness and sharpness as perceived by a viewer is provided for.

In an embodiment, the one or more image forming elements are arranged such as to cover the at least one LED light source of the second plurality of LED light sources fully.

Thereby, a lighting device providing a resulting image output with further improved brightness and sharpness as perceived by a viewer is provided for.

In an embodiment, the one or more image forming elements are arranged next to or adjacent to the at least one LED light source of the second plurality of LED light sources.

Thereby a lighting device being simpler and more efficient to manufacture is provided for since only the cover sheet, or foam structure, or 3D print needs to be adapted to serve the different desired needs for specific images and/or textures.

In an embodiment, the one or more image forming elements are configured to form one coherent or non-coherent image at the light exit window.

Thereby, an image with an improved quality is formed at the light exit window.

In an embodiment, the lighting device comprises a controller, and the controller is configured to switching between the first plurality of LED light sources and the second plurality of LED light sources.

Alternatively, or additionally, the controller may be configured to control the modulation of the first plurality of LED light sources and the modulation of the second plurality of LED light sources independently from one another.

By introducing such switching between, or modulation of, the different pluralities of LED light sources, an at least gradual change of surface state appearance is allowed for, without for example having to change the imaging elements.

In an embodiment, the first plurality of LED light sources are arranged in a first plane, where the second plurality of LED light sources are arranged in a second plane, and where the first plane is different from the second plane.

Thereby, a lighting device being structurally simple is obtained. Furthermore, such a configuration adds stiffness and thus robustness to the construction of the lighting device.

In an embodiment, the first plurality of LED light sources are arranged recessed with respect to the second plurality of LED light sources. Alternatively, the first plurality of LED light sources are arranged protruding with respect to the second plurality of LED light sources.

Thereby, a lighting device being particularly structurally simple is obtained. Furthermore, such a configuration adds further stiffness and thus robustness to the construction of the lighting device, and especially to the carrier plate.

In an embodiment, the lighting device comprises a driver, where the driver is configured to drive the first plurality of LED light sources in a first state, and where the first state is always the same state.

It is noted that with the term “same state” as used in this connection it is intended to mean that the appearance of the light exit window is uniform, but not always of the same brightness. Thereby, the desired homogeneous illumination provided by the first plurality of LED light sources is obtained in a particularly simple manner.

In an embodiment, the driver is further configured to drive at least a part of the LEDs of the second plurality of LED light sources in a second state, where the second state is the same as the first state, or where the second state is different from the first state.

Thereby, a lighting device which may simulate different textures is obtained in a particularly simple manner.

In an embodiment, the first plurality of LED light sources are arranged in a regular pattern, and the second plurality of LED light sources are arranged in any one of a regular pattern and an irregular pattern.

By arranging the first plurality of LED light sources in a regular pattern, the desired homogeneous illumination provided by the first plurality of LED light sources is obtained in a particularly simple manner.

By arranging the second plurality of LED light sources in a regular pattern, homogeneous illumination by the second plurality of LED light sources is obtained in a particularly simple manner.

By arranging the second plurality of LED light sources in an irregular pattern, inhomogeneous illumination by the first plurality of LED light sources is obtained in a particularly simple manner. This in turn provides for further options as regards the variation of simulated scenery being possible.

In an embodiment, the second plurality of LED light sources are arranged or grouped only at a part of the light exit window.

Thereby, a lighting device which may simulate different textures in only a part of the image is obtained in a particularly simple manner.

In an embodiment, the first plurality of LED light sources and the second plurality of LED light sources generate white light having a substantially identically correlated color temperature, CCT, and the image forming elements are clear elements.

Thereby the environmental layer provided by the lighting device appears natural to the viewer. Thus, such a lighting device provides for an output with a high perceptive quality.

The term “white light” herein, is known to the person skilled in the art. It especially relates to light having a correlated color temperature (CCT) between about 1800 K and 20000 K, such as between 2000 and 20000 K, especially 2700-20000 K, for general lighting especially in the range of about 2700 K and 6500 K. In embodiments, for backlighting purposes the correlated color temperature (CCT) may especially be in the range of about 7000 K and 20000 K. Yet further, in embodiments the correlated color temperature (CCT) is especially within about 15 SDCM (standard deviation of color matching) from the BBL (black body locus), especially within about 10 SDCM from the BBL, even more especially within about 5 SDCM from the BBL.

In an embodiment, any one or more of the first plurality of LED light sources, the second plurality of LED light sources and the image forming elements comprise a color.

Thereby the environmental layer provided by the lighting device in a particular high degree appears natural to the viewer. Thus, such a lighting device provides for an output with a particularly high perceptive quality.

In an embodiment, the lighting device may further comprise at least one further plurality of LED light sources adapted for, in operation, emitting further LED light source light, and thus at least three pluralities of LED light sources in total.

Thereby, immersive light experiences with an even higher degree of complexity may be simulated by the lighting device.

In an embodiment, the at least one further plurality of LED light sources comprises one or more further image forming elements, the lighting device further comprises a driver, and the driver is configured to drive the at least one further plurality of LED light sources.

For instance, the second plurality of LED light sources comprising one or more image forming elements may be used to form one part of an image, such as for example a branch. The at least one further plurality of LED light sources comprising one or more further image forming elements may be used to form another part of the image, such as for example leaves. The driver may therefore further be configured to drive the second plurality of LED light sources and the at least one further plurality of LED light sources separately or simultaneously.

Thereby an even larger variety of immersive light experiences may be simulated by the lighting device.

It is noted that the invention relates to all possible combinations of features recited in the claims.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

### BRIEF DESCRIPTION OF THE DRAWINGS

This and other aspects of the present invention will now be described in more detail, with reference to the appended drawings showing embodiment(s) of the invention.

FIG. 1 shows a cross-sectional side view of a lighting device according to a first embodiment of the invention.

FIG. 2 shows a cross-sectional side view of a lighting device according to a second embodiment of the invention.

FIG. 3 shows a cross-sectional side view of a lighting device according to a third embodiment of the invention.

FIG. 4 shows a cross-sectional side view of a lighting device according to a fourth embodiment of the invention.

FIG. 5 shows a schematical perspective view of an exemplary lighting device according to the invention in an exemplary imaging state.

As illustrated in the figures, the sizes of layers and regions are exaggerated for illustrative purposes and, thus, are provided to illustrate the general structures of embodiments of the present invention. Like reference numerals refer to like elements throughout.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

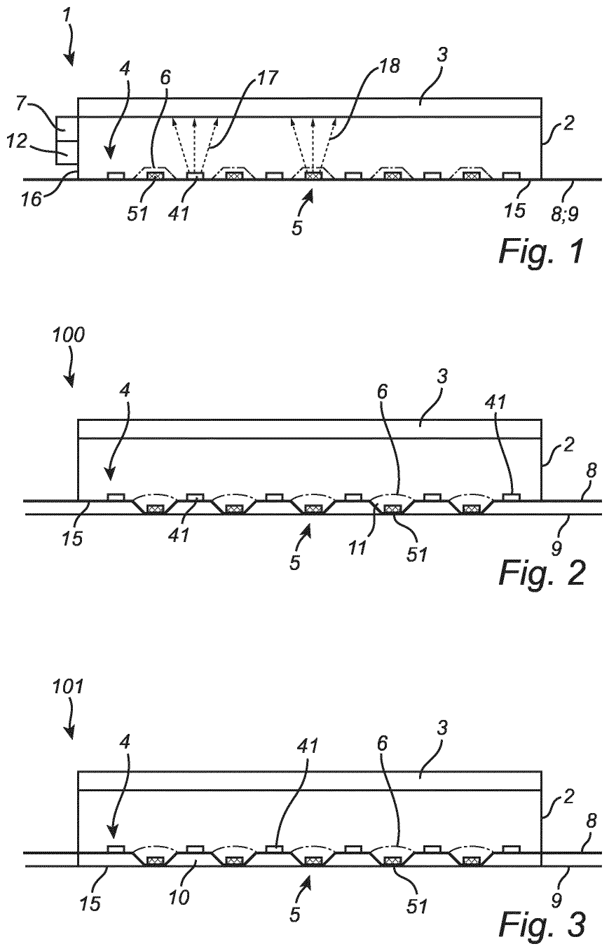

FIG. 1 shows a cross-sectional side view of a lighting device 1 according to a first embodiment of the invention. The lighting device 1 is generally and irrespective of the embodiment configured for providing a viewer with immersive light experiences.

Generally, and irrespective of the embodiment, the lighting device 1 comprises an optical light mixing unit 2, a first plurality of LED light sources 4 and a second plurality of LED light sources 5.

The optical light mixing unit 2 comprises a light exit window 3. The light exit window 3 is a diffuse light exit window 3. The optical light mixing unit 2 further comprises a bottom or bottom surface 15 and a circumferential side surface 16. The diffuse light exit window 3 and the bottom surface 15 extend parallel to and spaced apart from one another. The circumferential side surface 16 connects the diffuse light exit window 3 and the bottom surface 15.

The LEDs 41 of the first plurality of LED light sources 4 are adapted for, in operation, emitting first LED light source light 17. The first plurality of LED light sources 4 are non-imaging LED light sources. The LEDs 41 of the first plurality of LED light sources 4 are arranged such as to, in operation, enable homogeneous illumination of the light exit window 3. The LEDs 41 of the first plurality of LED light sources 4 may be arranged in a regular pattern. The first plurality of LED light sources 4 may comprise a color. The first plurality of LED light sources 4 may comprise a first correlated color temperature, CCT.

The LEDs 51 of the second plurality of LED light sources 5 are adapted for, in operation, emitting second LED light source light 18. The second plurality of LED light sources 5 are imaging LED light sources. At least one LED light source 51 of the second plurality of LED light sources 5 comprises an image forming element 6. It is also feasible that the at least one LED light source 51 of the second plurality of LED light sources 5 may comprise more than one an image forming element 6. In the embodiment shown in FIG. 1, each LED 51 of the second plurality of LED 5 comprises an image forming element 6. The second plurality of LED light sources 5 may comprise a color. The second plurality of LED light sources 5 may comprise a second correlated color temperature, CCT. The first CCT and the second CCT may be the same CCT. Alternatively, the first CCT and the second CCT may be mutually different. Alternatively, the CCT of second light may span a range of CCTs (nature does not come in a single shade of color, it comes in shades of different greens, for example. So, there is less need for using so called binned LEDs—LEDs having near the same specs in the operating point).

The LEDs 51 of the second plurality of LED light sources 5 are arranged between the LEDs 41 of the first plurality of LED light sources 4. Thereby, the LEDs 51 of the second plurality of LED light sources 5 provide non-homogeneous illumination of the light exit window 3. The LEDs 51 of the second plurality of LED light sources 5 may be arranged in a regular pattern or in an irregular pattern. For instance, LEDs 51 of the second plurality of LED light sources 5 may be arranged or grouped only at a part of the light exit window 3, that is such as to, in operation, illuminate only a part of the light exit window 3.

The first plurality of LED light sources 4 are arranged in a first plane 8. The second plurality of LED light sources 5 are arranged in a second plane 9. In the embodiment shown in FIG. 1, the first plane 8 and the second plane 9 coincide.

The first plurality of LED light sources 4 and the second plurality of LED light sources 5 may be arranged on a respective substrate, such as a printed circuit board (PCB). The respective substrate may comprise electrical circuitry for electrically supplying the LEDs 41 and 51. The first plurality of LED light sources 4 and the second plurality of LED light sources 5 may be arranged on one and the same substrate or on mutually different substrates. The substrates are for the sake of simplicity not shown in the figures. The substrates may form part of the bottom surface 15 of the light mixing unit 2 or be arranged on the bottom surface 15 of the light mixing unit 2.

The image forming elements 6 may be arranged such as to cover the at least one LED light source 51 of the second plurality of LED light sources 5 partially or fully. The image forming elements 6 may also be arranged next to or adjacent to the at least one LED light source 51 of the second plurality of LED light sources 5. The image forming elements 6 may be any one or more of reflective and opaque and transparent and translucent. For instance, opaque image forming elements yield a “hard” (shadow) image. An example of a translucent image forming element 6 is a sheet of rice paper. The image forming elements 6 may be micro-sheets, a suitable foam, fibers, or porous 2D-printed or 3D-printed structures. The image forming elements 6 may be configured to form one coherent or non-coherent image at the light exit window 3. The image forming elements 6 may comprise a color or be colored. The image forming elements 6 may also be clear elements. Clear image forming elements are especially suitable in embodiments where the first CCT of the first plurality of LED light sources 4 and the second CCT of the second plurality of LED light sources 5 are the same CCT.

The lighting device 1 may further optionally comprise a controller 7. The controller 7 may be configured to switch between the first plurality of LED light sources 4 being emitting light 17 and the second plurality of LED light sources 5 being emitting light 18. The controller 7 may be alternatively or additionally be configured to control the modulation of the first plurality of LED light sources 4 and the modulation of the second plurality of LED light sources 5 independently from one another.

The lighting device 1 may further optionally comprise a driver 12. The driver 12 is configured to drive the first plurality of LED light sources 4 and a part or all LEDs of the second plurality of LED light sources 5. The driver 12 may be configured to drive the first plurality of LED light sources 4 in a first state, the first state always being the same state. The driver 12 may further be configured to drive the second plurality of LED light sources 5 in a second state. The second state may be the same as the first state. Alternatively, the second state may be different from the first state. The driver 12 and the controller 7 may be one and the same unit.

FIG. 2 shows a cross-sectional side view of a lighting device 100 according to a second embodiment of the invention. The lighting device 100 shown in FIG. 2 differs from that described above in relation to FIG. 1 in virtue of the following features.

The second plurality of LED light sources 5 are arranged recessed with respect to the first plurality of LED light sources 4. More particularly, the LEDs 51 of the second plurality of LED light sources 5 are each arranged in a recess 11. Put in other words, the first plurality of LED light sources 4 are arranged protruding with respect to the second plurality of LED light sources 5. In an alternative, the first plurality of LED light sources 4 may be arranged recessed with respect to the second plurality of LED light sources 5.

The first plurality of LED light sources 4 are arranged in a first plane 8. The second plurality of LED light sources 5 are arranged in a second plane 9. In the embodiment shown in FIG. 2, the first plane 8 and the second plane 9 do not coincide. The first plane 8 and the second plane 9 are thus different planes. In the embodiment shown in FIG. 2, the first plane 8 coincides with the bottom surface 15 of the light mixing unit 2. The recesses 11 are provided in the bottom surface 15 of the light mixing unit 2.

FIG. 3 shows a cross-sectional side view of a lighting device 101 according to a third embodiment of the invention. The lighting device 101 shown in FIG. 3 is very similar to that described above in relation to FIG. 2 but differs in virtue of the following features.

The first plurality of LED light sources 4 are arranged protruding with respect to the second plurality of LED light sources 5. More particularly, the LEDs 41 of the first plurality of LED light sources 4 are each arranged on a protrusion 10. Put in other words, the second plurality of LED light sources 5 are arranged recessed with respect to the first plurality of LED light sources 4.

The first plurality of LED light sources 4 are arranged in a first plane 8. The second plurality of LED light sources 5 are arranged in a second plane 9. In the embodiment shown in FIG. 3, the first plane 8 and the second plane 9 do not coincide. The first plane 8 and the second plane 9 are thus different planes. In the embodiment shown in FIG. 3, the second plane 9 coincides with the bottom surface 15 of the light mixing unit 2. The protrusions 10 are provided on the bottom surface 15 of the light mixing unit 2.

FIG. 4 shows a cross-sectional side view of a lighting device 102 according to a third embodiment of the invention. The lighting device 101 shown in FIG. 3 differs from those described above in relation to FIGS. 1-3 in virtue of the following features.

The lighting device comprises a further plurality of LED light sources 13, and thus three pluralities of LED light sources 4, 5, 13 in total. The LEDs 131, 132 of the further plurality of LED light sources 13 are adapted for, in operation, emitting further LED light source light 19. It is noted that lighting devices according to the invention and comprising more than three pluralities of LED light sources in total may also be envisaged.

In the embodiment shown on FIG. 4, the first plurality of LED light sources 4 comprises six LEDs 41, the second plurality of LED light sources 5 comprises three LEDs 51, 52, 53 and the further plurality of LED light sources 13 comprises two LEDs 131, 132. The three pluralities of LED light sources 4, 5, 13 may also comprise other numbers of LEDs, respectively.

The at least one further plurality of LED light sources 13 further comprises one or more further image forming elements 141, 142. The one or more further image forming elements 141, 142 are similar to the image forming elements 6 described further above.

For instance, the second plurality of LED light sources 5 comprising one or more image forming elements 6 may be used to form one part of an image, such as for example a branch. The at least one further plurality of LED light sources 13 comprising one or more further image forming elements 141, 142 may be used to form another part of the image, such as for example leaves on the branch. The driver 12 may be configured to drive the second plurality of LED light sources 5 and the at least one further plurality of LED light sources 13 separately or simultaneously. The driver 12 may also be configured to drive a part or all of the LEDs of the at least one further plurality of LED light sources 13.

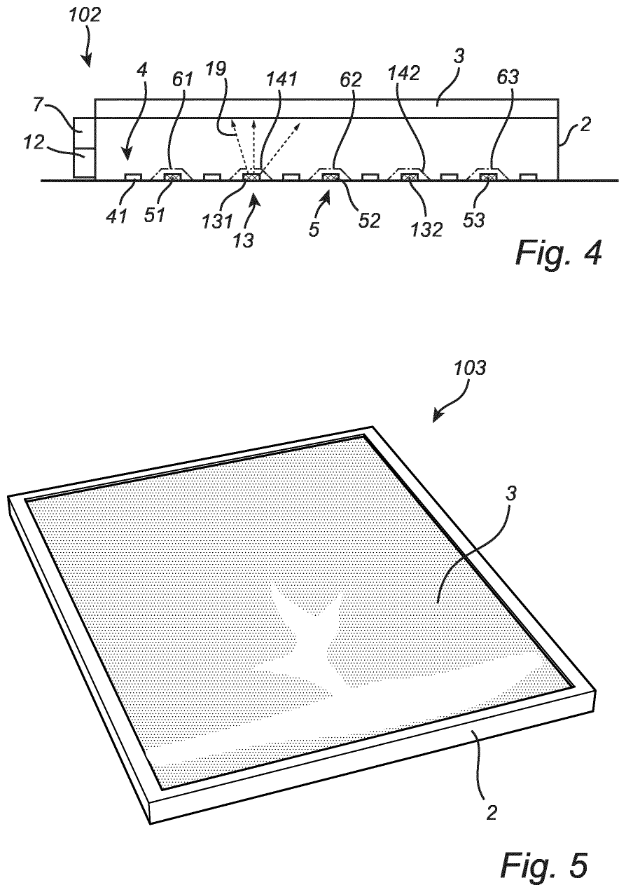

Turning now to FIG. 5, a schematical perspective top view of an exemplary lighting device 103 according to the invention in an exemplary imaging state is shown. The pluralities of LED light sources 4, 5 and the imaging elements 6 are not visible in FIG. 5 since they are concealed underneath the diffuse light exit surface 3.

The lighting device 103 shown in FIG. 5 measures 60 cm×60 cm. The lighting device 103 is generally of the type shown in FIG. 1 and described above. The surface state shown in FIG. 5 only serves the purpose of illustration and are by no means limiting. Also, other sizes or surface areas of lighting devices than 60 cm×60 cm are feasible. In fact, the potential surface area may be as small as 48 cm×11 cm, and as large as up to 60 cm×180 cm, for example for functional light panels. For daylight panels one or more portions, or the whole, of the surface area may be modulated to provide environmental texture.

The person skilled in the art realizes that the present invention by no means is limited to the preferred embodiments described above. On the contrary, many modifications and variations are possible within the scope of the appended claims.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A lighting device configured for providing a viewer with immersive light experiences, the lighting device comprising:
an optical light mixing unit comprising a diffuse light exit window,
a first plurality of LED light sources adapted for, in operation, emitting first LED light source light, the first plurality of LED light sources being non-imaging LED light sources, and the first plurality of LED light sources being arranged such as to, in operation, homogeneously illuminate the diffuse light exit window, and
at least one second plurality of LED light sources adapted for, in operation, emitting second LED light source light, the second plurality of LED light sources being imaging LED light sources,
wherein at least one LED light source of the second plurality of LED light sources comprises one or more discrete image forming elements,
wherein the side and bottom walls of the optical lighting mixing unit are reflective for the first LED light source light,
wherein the LED light sources of the second plurality of LED light sources are arranged to emit light in a direct optical path to the diffuse light exit window, and
wherein the second plurality of LED light sources is arranged between the first plurality of LED light sources in an alternating two-dimensional arrangement of one more LED light sources of the second plurality of LED light sources and one or more LED light sources of the first plurality of LED light sources such as to, in operation, non-homogeneously illuminate the diffuse light exit window.

2. A lighting device according to claim 1, wherein the one or more discrete image forming elements are any one or more of:
one or more of reflective, opaque, translucent and transparent, and
chosen from the group comprising micro-sheets, foams, fibers, porous 2D-printed or 3D-printed structures, a patterned phosphor provided on the second plurality of LED light sources and a light detouring light guide.

3. A lighting device according to claim 1, wherein the one or more discrete image forming elements are arranged such as to cover the at least one LED light source of the second plurality of LED light sources partially or fully.

4. A lighting device according to claim 1, wherein the one or more discrete image forming elements are arranged next to or adjacent to the at least one LED light source of the second plurality of LED light sources.

5. A lighting device according to claim 1, wherein the one or more discrete image forming elements are configured to form one coherent or non-coherent image at the light exit window.

6. A lighting device according to claim 1, wherein the lighting device comprises a controller, and wherein the controller is configured to one or more of:
switching between the first plurality of LED light sources and the second plurality of LED light sources, and
control the modulation of the first plurality of LED light sources and the modulation of the second plurality of LED light sources independently from one another.

7. A lighting device according to claim 1, wherein the first plurality of LED light sources are arranged in a first plane, wherein the second plurality of LED light sources are arranged in a second plane, and wherein the first plane is different from the second plane.

8. A lighting device according to claim 7, wherein the first plurality of LED light sources are arranged recessed with respect to the second plurality of LED light sources, or wherein the first plurality of LED light sources are arranged protruding with respect to the second plurality of LED light sources.

9. A lighting device according to claim 1, wherein the lighting device comprises a driver, wherein the driver is configured to drive the first plurality of LED light sources in a first state, and wherein the first state is always the same state.

10. A lighting device according to claim 9, wherein the driver is configured to drive at least a part of the LEDs of the second plurality of LED light sources in a second state, wherein the second state is the same as the first state, or wherein the second state is different from the first state.

11. A lighting device according to claim 9, wherein the lighting device further comprises at least one further plurality of LED light sources adapted for, in operation, emitting further LED light source light, wherein the at least one further plurality of LED light sources comprises one or more further image forming elements, and wherein the driver is configured to drive the at least one further plurality of LED light sources.

12. A lighting device according to claim 1, wherein the first plurality of LED light sources are arranged in a regular pattern, and wherein the second plurality of LED light sources are arranged in any one of a regular pattern and an irregular pattern.

13. A lighting device according to claim 1, wherein the second plurality of LED light sources are arranged or grouped only at a part of the light exit window.

14. A lighting device according to claim 1, wherein any one or more of the first plurality of LED light sources, the second plurality of LED light sources and the image forming elements comprise a color.

15. A lighting device according to claim 1, wherein the first plurality of LED light sources and the second plurality of LED light sources generate white light having a substantial identically correlated color temperature, CCT, and wherein the image forming elements are clear elements.
